(19) United States
(12) Patent Application Publication
(10) Pub. No.: US 2023/0373781 A1
(43) Pub. Date: Nov. 23, 2023

(54) MEMS ACTUATOR, IN PARTICULAR A MICROMIRROR, WITH INCREASED DEFLECTABILITY

(71) Applicant: Hahn-Schickard-Gesellschaft für angewandte Forschung e. V., Villingen-Schwenningen (DE)

(72) Inventors: Jan Rockstroh, St. Georgen (DE); Achim Bittner, Heilbronn (DE); Daniel Hoffmann, Unterkirchnach (DE); Alfons Dehé, Reutlingen (DE)

(21) Appl. No.: 18/319,154

(22) Filed: May 17, 2023

(30) Foreign Application Priority Data
May 18, 2022 (EP) 22174041.8

(51) Int. Cl. B81B 3/00; B81C 1/00; G02B 26/08

(52) U.S. Cl. CPC B81B 3/0043; B81C 1/00158; G02B 26/0833; B81B 2201/032; B81B 2201/042; B81B 2203/0118; B81C 2201/0132; B81B 2203/055; B81B 2203/0127

(57) ABSTRACT

A MEMS actuator comprising a frame structure and at least one actuator arm. The actuator arm is connected at a first end to the frame structure and at a second end to an actuator body. The MEMS actuator is characterized in that the at least one actuator arm has a meander structure comprising two or more actuator sections. The two or more actuator sections are oriented substantially perpendicular to the longitudinal axis of the actuator arm. Furthermore, the two or more actuator sections comprise at least one layer of an actuator material, wherein a movement of the actuator body can be effected by actuating the two or more actuator sections. Further disclosed is a method for producing the MEMS actuator.

The invention relates to a MEMS actuator comprising a frame structure and at least one actuator arm. The actuator arm is connected at a first end to the frame structure and at a second end to an actuator body. The MEMS actuator is characterized in that the at least one actuator arm has a meander structure comprising two or more actuator sections. The two or more actuator sections are oriented substantially perpendicular to the longitudinal axis of the actuator arm. Furthermore, the two or more actuator sections comprise at least one layer of an actuator material, wherein a movement of the actuator body can be effected by actuating the two or more actuator sections.

Furthermore, the invention relates to a method for producing the MEMS actuator according to the invention.

### BACKGROUND AND PRIOR ART

Today, microsystems technology is used in many fields of application for the production of compact, mechanical-electronic devices. The microsystems (micro electro mechanical systems, MEMS for short) that can be produced in this way are very compact (approx. in the micrometer range) with excellent functionality and ever lower production costs.

Actuators are also known from the prior art that are based on operating principles and/or production methods of microsystems technology. Actuators generally refer to components that convert a control signal, e.g. in the form of an electrical control signal, into mechanical movements and/or changes in physical variables, such as a pressure and/or a temperature. Actuators in the context of microsystems technology are also referred to as MEMS actuators.

In Algamili et al. (2021), an overview of the construction and operation of known prior art MEMS actuators is disclosed. MEMS actuators can be classified according to a wide variety of criteria, in particular according to their operating principle. Thus, MEMS actuators are known that operate according to electrostatic, piezoelectric, electromagnetic or thermal principles. With the first three principles, electrical energy is typically converted directly into mechanical energy. With the thermal (drive) principle, the electrical energy is first converted into thermal energy, followed by conversion into mechanical energy due to thermal expansion.

MEMS actuators have a high number of applications. For example, MEMS actuators can be used to move and/or position an associated micromirror to a desired position. Micromirrors are used in many fields. Among other things, micromirrors are used in automotive technology in the context of LiDAR, which stands for Light Detection and Ranging and is a method for distance measurement and environment detection. Micromirrors are used to emit light at high scanning speeds over large angular ranges onto corresponding objects and to carry out distance measurements. Dingkang, Watkins & Xie (2020) discusses LiDAR technology and the requirements for the design and function of micromirrors for these applications.

Micromirrors are particularly relevant in the context of display or projection technology, for example the so-called DLP technology, which stands for digital light processing. DLP is used, for example, for video projectors and rear projection screens in the home cinema and presentation sector. DLP is also used in the industrial sector for additive production. Furthermore, the technology is used in biology and medicine for optical examination methods. Katal, Tyagi & Joshi (2013) provides an introduction to DLP technology and discusses its use in (potential) fields of application.

The basis of DLP technology is the DMD (Digital Micromirror Device). The mode of operation of DMDs is described, for example, in Lee (2008) as well as the basic patent U.S. Pat. No. 5,061,049. A DMD comprises a plurality of micromirrors arranged according to an array, for example in the form of a matrix in a rectangular field. Each micromirror corresponds to one pixel of an image to be displayed. The micromirrors can be rotated individually by approximately ±10°-12° to turn them on or off. When switched on, the light from a projector light source is reflected towards an optical system, for example a lens, in such a way that the pixels on the screen appear bright. When switched off, the light is directed in a different direction, causing the pixel to appear dark. To create greyscales, for example, the mirror is switched on and off very quickly. The ratio of on-time to off-time determines the color tone of the image to be projected. To be able to illuminate a large projection surface, the possible deflection angles are relevant. The movability of the micromirror has a decisive influence on the presentation of the projection image as such.

Micromirrors are also needed as components of microscanners (see e.g. Holmström, Baran & Urey (2014)). Depending on the design, the modulating motion of a micromirror can be translational or rotational about one or two axes. In the first case, a phase-shifting effect is achieved, while in the second case the deflection of the incident light beam is effected. Microscanners can be used, for example, in laser displays or resonance scanners.

Laser display applications also require large deflections of a mirror combined with high-precision movement. Resonant scanners use a high mechanical quality factor (Q) to achieve the required angle of the micromirror. At atmospheric pressure, a very high drive torque is required to overcome air damping. This problem can be solved by using a vacuum package, but this is costly and introduces a number of other technical problems.

Thus, in the prior art, especially for the movement of micromirrors, there is a need to provide MEMS actuators that optimize the deflectability as well as the movement. In particular, dynamic deflection over a large angular range should be possible.

With regard to the use of micromirrors in laser scanning or projection systems, for example, an improved resolution over a larger image area should be achieved. Likewise, in the context of LiDAR systems, a large deflection of the micromirrors is desirable in order to increase the scanning field or field of view (FoV). For self-driving cars, for example, the minimum field of view should be at least 25°, while gesture recognition even requires 50° and blind spot detection 120° or more (see also Watkins & Xie (2020)). At the same time, the micromirrors must meet high requirements for precision and scanning speed.

In the case of known MEMS actuators of the prior art, there is therefore a need for improvement in the actuation of micromirrors with regard to the deflection as such as well as with regard to the dynamics, whereby it would also be desirable to be able to provide suitable MEMS actuators for this purpose by means of process-efficient procedures.

### OBJECTIVE OF THE INVENTION

The objective of the invention was to provide a MEMS actuator that eliminates the disadvantages of the prior art. In particular, a MEMS actuator was to be provided with which large deflection angles of an actuator body, for example of a micromirror, are made possible, preferably with simultaneously high-precision movement and high dynamics. Furthermore, the MEMS actuator should preferably be characterized by a robust, compact design and more effective production process.

### SUMMARY OF THE INVENTION

The objective according to the invention is solved by the independent claims. Advantageous embodiments of the invention are disclosed in the dependent claims.

In a first aspect, the invention preferably relates to a MEMS actuator comprising a frame structure and at least one actuator arm, wherein the actuator arm is connected at a first end to the frame structure and at a second end to an actuator body, characterized in that the at least one actuator arm has a meander structure comprising two or more actuator sections, wherein the two or more actuator sections are aligned substantially perpendicular to a longitudinal axis of the actuator arm and comprise at least one layer of an actuator material and wherein a movement of the actuator body can be effected by actuating the two or more actuator sections.

The preferred MEMS actuator has proven to be advantageous in many ways and shows significant improvements over the prior art.

A particular advantage of the preferred MEMS actuator is the effect that high deflections of the actuator body can be achieved. The greater deflections advantageously affect all spatial dimensions and can manifest themselves, for example, in high tilt angles. Here, the tilt angle preferably denotes an angle or inclination, relative to an initial position of the actuator body, in the vertical direction to the longitudinal axis of the actuator arm. In general, it is advantageously possible to achieve particularly high deflections of the actuator body, whereby a deflection here preferably means a change in an initial position of the actuator body.

High deflections or tilting angles of the actuator body result from the design of the actuator arm, according to which it has a meandering structure with two or more actuator sections which are aligned substantially perpendicular to the longitudinal axis.

When the actuator arm is actuated, the two or more actuator sections are excited simultaneously so that their force effect adds up to a larger moment or travel and causes a higher deflectability of the actuator body. Advantageously, the desired deflectability is scalable according to the number of actuator sections, which can be selected accordingly.

The inventors have recognized that a meander structure comprising two or more actuator sections can generate a higher moment of a force for actuating the actuator body by summing the effect of the individual actuator sections. Preferably, the moment of a force means a torque, i.e. in particular the product of the force and a distance. The interaction of a plurality of actuator sections results in a higher moment and thus a higher deflectability and/or a higher tilt angle of the actuator body.

Providing a MEMS actuator with the ability to achieve higher tilt angles is advantageous for a variety of applications. For example, the prior art is known to seek to provide micromirrors that can be precisely and rapidly tilted over large angles for use in, for example, LiDAR systems, confocal microscopy and/or displays.

By designing the actuator body as a micromirror, for example in that it has a reflective surface at least in sections, the MEMS actuator according to the invention can transfer its advantages to these possible applications particularly effectively.

Another advantage of the preferred MEMS actuator is the possibility that the actuator body can be tilted in several spatial directions. In particular, the movement or movement options of the actuator body can be adapted in a process-efficient manner for corresponding application purposes, for example by attaching several actuator arms and/or fixing elements.

Advantageously, for example, the attachment of several actuator arms at several points of the actuator body allows a deflection in different tilting directions, as is desirable for two-dimensional movements, for example. By attaching a fixing element in combination with one or more actuator arms, a deflection of the actuator body along an axis or a point in one or more tilting directions can be effected.

Furthermore, the preferred MEMS actuator can be operated with a plurality of modes of action. Thus, advantageously, a potential user of the preferred MEMS actuator can select a principle of operation from a plurality of physical principles, for example, actuation by an electrical or thermal signal to cause the actuator body to move. The utilization of an actuator arm with a meander structure to move the actuator body is thus not limited to specific actuator principles.

Another advantage of the preferred MEMS actuator is its capacity for efficient production. Thus, the preferred MEMS actuator can be provided with common methods of microsystem and/or semiconductor technology, in particular the structuring of the meander structure as well as the design of the actuator arm. It is particularly advantageous that the preferred MEMS actuator can be produced from a substrate and thus a single process sequence. Thus, the production of the preferred MEMS actuator is suitable for mass production as well as process-efficient and at the same time leads to the provision of a compact and robust MEMS actuator.

For the purposes of the invention, a MEMS actuator preferably denotes an actuator which has structures and/or components with dimensions in the micrometer range and/or has been produced using methods of semiconductor and/or microsystem technology. In this context, the MEMS actuator is preferably capable of being converted into a physical quantity and/or into mechanical energy, e.g. into kinetic and/or potential energy, by means of actuation, for example by means of a control signal. Preferably, this is done by a deflection of the actuator body. As structural components, the MEMS actuator preferably comprises a frame structure, an actuator arm and an actuator body.

The frame structure preferably refers to a support for the actuator arm. The frame structure is preferably a structure which is substantially formed by a continuous outer border in the form of side walls of a free flat area. The frame structure is preferably stable and resistant to bending. In the case of an angular frame shape (triangular, quadrangular, hexagonal or generally polygonal outline), the individual side areas that essentially form the frame structure may also be referred to as side walls. In particular, the actuator arm may be connected to the frame structure.

The actuator arm preferably refers to that component of the MEMS actuator through which deflection of the actuator body is enabled. In particular, the actuator arm is a link between the actuator body and the frame structure. In this regard, the actuator arm has a first end and a second end. The first end and the second end of the actuator arm preferably denote end regions of the actuator arm. In particular, the first end and the second end may form connecting regions of the actuator arm. Preferably, the actuator arm is connected to the frame structure at the first end and is connected to the actuator body at the second end.

The actuator arm preferably has a meander structure comprising two or more actuator sections.

A meander structure is preferably a structure formed by a sequence of substantially orthogonal sections in cross-section. The mutually orthogonal sections are preferably vertical and horizontal sections, whereby the vertical sections are preferably formed by the actuator sections. Particularly preferably, the meander structure is rectangular in cross-section. However, it may also be preferred that the meander structure has a sawtooth shape (zigzag shape) in cross-section or is curvilinear or wave-shaped. This is particularly the case if the actuator sections are not aligned exactly parallel to each other, but enclose an angle of, for example, approx. ±30°, preferably approx. ±20°, particularly preferably approx. ±10° with a vertical direction.

Horizontal sections preferably denote structures through which the actuator sections, i.e. the vertical sections of the meander structure, are interconnected. In preferred embodiments, the horizontal sections are present connected to the actuator sections at an orthogonal angle of about 90° in the vertical direction. In further preferred embodiments, the horizontal sections may also not be exactly at an orthogonal angle of about 90° to the vertical direction, but may, for example, include an angle between about 60° and about 120°, preferably between about 70° and about 110°, particularly preferably between about 80° and about 100° with the vertical direction.

In the case of a curved or wavy shape of the actuator sections and/or horizontal sections of the actuator arm in cross-section, the alignment preferably refers to a tangent to the actuator sections and/or horizontal sections at their respective midpoints.

The meander structure thus preferably corresponds to a membrane folded along the width. In the sense of the invention, the actuator arm can therefore preferably also be called a bellows. The parallel folds of the bellows are preferably formed by the vertical sections or actuator sections. The connecting sections between the folds are preferably formed by the horizontal sections. Preferably, the actuator sections that are substantially vertically oriented are longer than the horizontal sections, for example by a factor of 1.5, 2, 3, 4 or more.

The actuator sections preferably designate structures of the actuator arm or the meander structure of the actuator arm, which are arranged substantially in a vertical orientation. In a preferred embodiment, the actuator sections are oriented substantially parallel to the vertical direction, wherein substantially parallel means a tolerance range of about ±30°, preferably about ±20°, particularly preferably about ±10° about the vertical direction. The actuator sections can preferably also be referred to as vertical sections of the meander structure.

The directions vertical and horizontal (or lateral) preferably refer to a preferred direction in which the actuator arm is aligned for deflection and/or movement of the actuator body. Preferably, the actuator arm is suspended horizontally from at least one side region of the frame structure, while the vertical direction is substantially orthogonal thereto.

The actuator sections of the actuator arm or the meander structure of the actuator arm thus preferably designate sections which are aligned substantially orthogonally to the horizontal suspension direction of the actuator arm. The person skilled in the art understands that this need not be an exact vertical orientation, but preferably a substantially vertical orientation.

The actuator arm with meander structure comprises two or more or more actuator sections, wherein the two or more actuator sections are oriented substantially perpendicular to a longitudinal axis of the actuator arm. Substantially perpendicular to a longitudinal axis of the actuator arm preferably refers to an orthogonal direction with respect to the suspension direction of the actuator arm. Thus, along its longitudinal axis, the actuator arm is preferably connected to the frame structure at least at its first end. The horizontal direction preferably corresponds substantially to the directions of the longitudinal axis of the actuator arm.

Preferably, a movement and/or deflection of the actuator body can be effected by actuating the two or more actuator sections. Actuation of the two or more actuator sections preferably denotes a transmission of effect to the two or more actuator sections, so that a movement and/or a deflection of the actuator body results from the actuation. The active transmission to the two or more actuator sections can preferably be effected by a control signal, for example in the form of an electrical signal.

For this purpose, it is preferred that the two or more actuator sections have at least one actuator material. The actuator material translates the actuation into a movement and/or deflection of the actuator body. For example, the actuator material may be a piezoelectric or thermosensitive material. Without wishing to be bound to a theory, the operating principles through the use of these materials as actuator material will be described in more detail in the further course.

Preferably, the actuator material in the actuator sections serves as a component of a mechanical bimorph, wherein a deflection and/or lateral bending of the actuator sections is preferably effected by actuating the actuator layer. Thus, the actuator sections may preferably comprise at least two layers, wherein a first layer comprises an actuator material and a second layer comprises a mechanical support material and/or wherein both layers comprise an actuator material. When actuated, the actuator material may, for example, undergo transverse or longitudinal stretching or compression relative to a mechanical support layer, thereby generating a stress gradient. Alternatively, a relative change in shape of two actuated actuator layers can be generated.

The resulting stress gradient between both layers of an actuator section can preferably cause a lateral bending and/or deflection of the actuator sections, which add up and thus lead to high deflections of the actuator body.

Especially in the case of a two-sided fixing of an actuator arm, a lateral bending of the actuator sections can occur. A lateral bending of the actuator sections preferably occurs if the connection points between the actuator section and the horizontal section are restricted in their movement. This can occur, for example, when two actuator arms are attached to both sides of an actuator body (see FIG. 5B).

If the actuator body is not fixed at one end of the actuator arm but is free (one-sided fixing of the actuator arm), the actuation of the actuator sections does not generally cause any lateral bending, but instead there is a deflection of the actuator sections, which add up over the length of the actuator arm to an overall deflection and/or tilting of the actuator body (see FIG. 5A). By deflection in the case of a single actuator arm, it is preferably meant that there is a change in the angle between the actuator section (vertical section) and the horizontal section of the actuator arm. The overall deflection of the actuator arm in case of attachment of the actuator body via a single actuator arm to the support also preferably results from a stress gradient between two layers of a mechanical bimorph. However, due to a one-sided fixing of the actuator arm, which allows a freer movement of the connection points between horizontal sections and actuator sections, the actuator sections do not experience any significant horizontal or lateral bending. Instead, there is preferably a deflection of the actuator sections in which the actuator sections retain a substantially straight course in cross-section (see FIG. 5A). The individual deflections of the actuator sections add up to a total deflection over the length of the actuator arm, with or without the occurrence of a lateral bending.

Consequently, a high deflection or tilting of the actuator body can be achieved by the design of the actuator arm, regardless of the number of actuator arms.

Preferably, the at least one actuator layer of the actuator arm is a continuous layer of actuator material. Continuous preferably means that there are no interruptions in the cross-sectional profile. Accordingly, it is preferred in said embodiment that there is a continuous layer of actuator material both in the actuator sections and in the horizontal sections. Advantageously, no structuring is necessary in the production process. A continuous layer is particularly easy to produce.

The actuator body preferably designates the component of the MEMS actuator which is to be deflected and/or moved for the respective intended use. Preferably, the actuator body is a structure that has larger dimensions than a horizontal section. Particularly preferably, the actuator body is a piece of a substrate which is connected at the second end of the substrate. With the aid of the preferred MEMS actuator, the actuator body can undergo deflection and/or movement via several forms of movement.

In a preferred embodiment, the MEMS actuator is characterized in that the movement of the actuator body comprises translation, rotation, torsion and/or tilting.

Advantageously, by means of the principle according to the invention, it is possible to provide a MEMS actuator for diverse forms of movement.

A translation preferably refers to a substantially rectilinear movement. Thus, a translation may concern a movement preferably along one or more axes or along or perpendicular to a plane. In preferred embodiments, the translation is a vertical translation in which the actuator body is moved orthogonally out of the plane of the one or more actuator arms. For example, two actuator arms may be mounted opposite each other on the actuator body (see FIG. 4).

A rotation or tilt preferably refers to a rotation of the actuator body along a rotation axis (also pivot axis) or a rotation point (also pivot point). During rotation around a rotation or pivot axis, points on the rotation axis remain in place while other points on the actuator body move around the axis at a fixed distance from it on a circle perpendicular to the axis through the same angle or at the same angular velocity.

A rotation point or pivot point can preferably be a point at which the actuator body is fixed (by appropriate measures, e.g. by attaching fixing elements) and a rotation or tilting is carried out around this point (see FIG. 3).

Likewise, a rotation or tilting of the actuator can be performed about a non-stationary axis of rotation. For example, the movement of the actuator body may comprise a superposition of rotation and translation. This may be the case, for example, if the actuator body is not connected to a fixing means. In this case, the actuator body can be connected to an actuator arm on one side, while the actuator body is otherwise free to move. By actuating the actuator arm on one side, a rotation or tilting of the actuator body is caused, while the actuator body (and thus the axis of rotation) moves alternately “downwards” and “upwards” (see FIG. 2).

Torsion preferably refers to a distortion of the actuator arm and/or the actuator body that results from the effect of a torsional moment. It may be preferred that the actuator body is connected to several actuator arms which cause a corresponding torsional moment.

In another preferred embodiment, the MEMS actuator is characterized in that the two or more actuator sections were formed by applying at least one layer comprising an actuator material onto a meander structure of a substrate, preferably wherein regions of the meander structure of the substrate were oriented orthogonally to the surface of the substrate to form the two or more actuator sections.

The MEMS actuator comprising an actuator arm with a meander structure is preferably formable from a substrate by means of a semiconductor process. For this purpose, the substrate is preferably etched, preferably starting from a front side, to form the structure, preferably a meander structure. Furthermore, it is preferred to apply at least one layer comprising an actuator material. Preferably, two layers are applied, wherein the two layers may be one layer comprising an actuator material and a mechanical support layer or two layers comprising an actuator material. Preferably, the mechanical bimorph is formed by applying two layers, wherein an actuator section is to be understood as a mechanical bimorph and this is arranged vertically to the substrate surface by the etching. The actuator arm is exposed by means of a preferred etching, preferably starting from a rear side.

The regions of a meander structure at which the actuator sections (vertical sections) of the actuator arm are formed are thus preferably substantially vertical to the substrate surface from which the frame structure and/or the actuator arm was formed. In the finished MEMS actuator, the actuator arm preferably extends substantially horizontally to the (original) substrate surface (e.g. a wafer), while the actuator sections are arranged vertically to the (original) substrate surface.

Preferably, the frame structure and/or the actuator body can be produced from the same substrate. Thus, the original orientation of the regions of the substrate through which the two or more actuator sections have been provided is recognizable on the frame structure and/or actuator body to an average person skilled in the art.

In another preferred embodiment, the MEMS actuator is characterized in that the two or more actuator sections comprise at least two layers, preferably wherein one layer comprises an actuator material and a second layer comprises a mechanical support material and/or wherein both layers comprise an actuator material.

Advantageously, the preferred arrangement comprising two layers comprising an actuator material or one layer comprising an actuator material and one layer comprising a mechanical support material can provide a highly efficient translation of the actuation by which the movement and/or deflection of the actuator body can be effected.

In a preferred embodiment, the two or more actuator sections comprise a layer comprising an actuator material and a layer comprising a mechanical support material.

Preferably, the layer of an actuator material in the actuator sections serves as a component of a mechanical bimorph, whereby a movement of the actuator body results from actuation of the actuator material, e.g. with the aid of an electrode, which is preferably in contact at the end.

Upon actuation of the layer comprising an actuator material (also referred to as actuator layer), this can, for example, experience a transverse or longitudinal stretching or compression. This creates a stress gradient with respect to the mechanical support layer, which leads to a lateral bending or deflection of the actuator layer. While the actuator layer undergoes a change in shape, e.g. by applying an electrical voltage, the position of the mechanical support material remains substantially unchanged. The resulting stress gradient between both layers can preferably cause a lateral bending or deflection of the actuator sections, which add up and thus lead to high deflections of the actuator body.

For the layer comprising the mechanical support material (also support layer), the thickness of the support layer is preferably to be selected in comparison to the thickness of the actuator layer such that a sufficiently large stress gradient is generated, which causes a lateral bending and/or deflection. For doped polysilicon as mechanical support material and a piezoelectric material such as PZT or AIN as actuator material, for example, substantially equal thicknesses, preferably between approx. 0.5 μm and approx. 2 μm, have proven to be particularly suitable.

For the purposes of the invention, the layer comprising a mechanical support material is preferably also referred to as a support layer. The mechanical support material or the support layer preferably serves as a passive layer which can resist a change in shape of the actuator layer (layer comprising actuator material). In contrast to an actuator layer, the mechanical support material preferably does not change its shape due to actuation, for example when an electrical voltage is applied. Preferably, the mechanical support material is electrically conductive so that it can also be used directly for contacting the actuator layer. However, in some embodiments it can also be non-conductive and, for example, be coated with an electrically conductive layer.

Preferably, the mechanical support material is selected from a group comprising monocrystalline silicon (monosilicon), polycrystalline silicon (polysilicon) and/or a doped polysilicon.

In a preferred embodiment, the two or more actuator sections comprise at least two layers comprising an actuator material. In this embodiment, the movement of the actuator body is thus not generated by a stress gradient between an active actuator layer and a passive support layer, but by a relative change in shape of two active actuator layers. The actuator layers can consist of the same actuator material. The actuator layers can also consist of different actuator materials, for example piezoelectric materials with different deformation coefficients.

For the purposes of the invention, the layer comprising an actuator material is preferably also referred to as an actuator layer. An actuator material preferably means a material which undergoes a change of shape by being actuated by a control signal, for example by applying an electrical voltage, and/or conversely generates an electrical voltage by changing its shape. The change in shape can occur, for example, through stretching, compression or shearing.

Preferably, materials with electric dipoles are chosen as actuator material, which undergo a change of shape by the application of an electric voltage, whereby the orientation of the dipoles and/or the electric field can determine the preferred direction of the shape changes.

In another preferred embodiment, the MEMS actuator is characterized in that the actuator material comprises a piezoelectric material, a polymer piezoelectrical material, electroactive polymers (EAP) and/or a thermosensitive material.

The aforementioned materials have proven to be particularly advantageous for use as actuator materials in the context of the preferred MEMS actuator. Thus, they translate particularly well the preferred actuation by a control signal into movements and/or deflections of the actuator body.

Particularly preferably, the piezoelectric material is selected from a group comprising lead zirconate titanate (PZT), aluminum nitride (AlN), aluminum scandium nitride (AlScN) and/or zinc oxide (ZnO).

Polymer piezoelectric materials (also known as piezoelectric polymer materials) preferably include polymers that have internal dipoles and piezoelectric properties mediated by them. This means that when an external electrical voltage is applied, the polymer piezoelectric materials (analogous to the aforementioned classic piezoelectric materials) undergo a change in shape (e.g. compression, stretching or shearing). An example of a preferred polymer piezoelectric material is polyvinylidene fluoride (PVDF).

Thermosensitive materials preferably refer to materials that cause movement of the actuator body with the help of sufficient deformation through a thermal effect. For example, thermosensitive materials can have a bimetal and thus use a bimetal effect. A bimetal comprises a sandwich structure comprising two different layers (bimorph) that have different coefficients of thermal expansion and can be heated by a heating element and then deformed. For example, silicon, silicon dioxide and/or gold can be used as preferred thermosensitive materials, especially in the case of a bimetal, material combinations of silicon and gold and/or silicon and silicon dioxide.

In a further preferred embodiment, the MEMS actuator is characterized in that the actuator arm is in contact with at least one electrode and preferably the actuator sections are actuated by an electrical control signal.

Preferably, the at least one electrode is positioned at the end so that contact can be made with electronics, e.g. a current or voltage source, at one end of the actuator arm, preferably at an end at which the actuator arm is suspended from the frame structure. Electrode preferably means a region made of a conductive material (preferably a metal) which is adapted for such contacting with electronics, e.g. a current and/or voltage source. Preferably, it can be an electrode pad. Particularly preferably, the electrode pad is used for contacting with electronics and is itself connected to a conductive metal layer, which can extend over the entire surface of the actuator arm.

For this purpose, it may be preferred to apply a layer comprising an electrically conductive material to the actuator layer and/or the support layer. The layer comprising the electrically conductive material can preferably be applied on a front side and/or preferably on a back side of the actuator material. A layer comprising an electrically conductive material on a front side is preferably referred to as a top electrode. Similarly, a layer comprising an electrically conductive material on a rear side is preferably referred to as a bottom electrode. In part, the conductive layer together with an electrode pad is hereinafter referred to as an electrode, for example a top electrode or a bottom electrode.

Particularly preferably, a layer of a conductive material, preferably a metal, in the sense of a top or bottom electrode is present as a continuous or full-surface or contiguous layer of the actuator arm, which forms a substantially homogeneous surface and in particular is not structured. Instead, the two or more actuator sections are preferably contacted with one or two end-sided electrodes by means of an unstructured layer of a conductive material, preferably metal.

In preferred embodiments, the MEMS actuator comprises two end-sided electrodes. Preferably, contact with electronics, e.g. a current and/or voltage source, can be made with the electrodes at the end of the actuator arm where it is suspended from the frame structure.

The electrical control signal is preferably generated by electronics, for example by a current and/or voltage source, which causes deflections and/or lateral bendings of the actuator sections.

In a further preferred embodiment, the MEMS actuator is characterized in that the MEMS actuator comprises a fixing element which is connected to the actuator body such that the actuator body can be tilted along a pivot point and/or a pivot axis by applying the control signal.

Advantageously, with the help of a fixing element, both the direction and the deflection of the actuator body can be specified, such that a deflection can be carried out in the desired manner in the form of a tilt.

A fixing element preferably refers to a component of the MEMS actuator to which the actuator body can be fixed along an axis and/or at a point. The fixing element may be thus also referred to as a fixation element, fixation component and preferably relates to a structure that limits the degree of freedom of the actuator body to an axis or point. the fixing element may also be referred to as a hinge allowing for either a rotation about an axis or a point. Thus, the actuator body can perform rotation and/or tilting along this axis (axis of rotation) and/or point (point of rotation). The fixing element for rotation and/or tilting along an axis of rotation can be provided, for example, by leaving a piece of the substrate during production and connecting it to the actuator body. The piece of the substrate may be in form of a rod (for limiting the degree of freedom to an axis) or a pointy structure (for limiting the degree of freedom to a point).

The fixing element for rotation and/or tilting along a pivot point can also be done, for example, by attaching a MEMS torsion spring. The MEMS torsion spring preferably allows the actuator body to be rotated in a certain direction of rotation and the rotation of the actuator body in other directions to be restricted.

Likewise, the fixing element for rotation and/or tilting along a pivot point can also be provided by a micro-joint.

In another preferred embodiment, the MEMS actuator is characterized in that the first end of the actuator arm is connected to the frame structure via a mechanically rigid or flexible connector.

A connector preferably means a component that is present as an intermediate component between the actuator arm and the frame structure. Preferably, the connector is attached to the first end of the actuator arm, so that the connector can preferably also be understood as part of the actuator arm.

Advantageously, the placement of a connector between the actuator arm and the frame structure results in a particularly reliable connection. Furthermore, the connector facilitates the movability of the actuator body.

In the case of a mechanically flexible connector, there is advantageously a reduced mechanical resistance at the first end and thus at the connection point of the actuator arm with the frame structure, such that the movement of the actuator body takes place with particularly low mechanical resistance. In addition to flexibility, a mechanically flexible connector is preferably characterized by elastic properties in order to ensure a restoring force to a preferred position. Preferably, a mechanically flexible connector may be a MEMS spring. The MEMS spring as a mechanically flexible connector can, for example, be designed as a double folded beam, have a U-shape or be in the form of a fish-hook spring.

A mechanically rigid connector preferably refers to a connector that is substantially immovable and/or non-deformable by a movement of the actuator body. A mechanically rigid connector has been found to provide a particularly stable and robust connection between the actuator arm and the frame structure and is suitable for those applications where a high mechanical resistance at the first end of the actuator arm is desired. The mechanically rigid connector may preferably be attached as part of the substrate or frame structure during production of the MEMS actuator.

In a further preferred embodiment, the MEMS actuator is characterized in that, by actuating the two or more actuator sections, the actuator body can be tilted by at least approx. 10°, preferably by at least approx. 20°, particularly preferably by at least approx. 40°, very particularly preferably by at least approx. 60°. The aforementioned possible tilting angles preferably denote angles in a direction of rotation about which the actuator body can be tilted or rotated. An alternating tilting movement of the actuator body can preferably take place with tilting angles of at least approx. ±10°, ±20°, ±40°, ±60° or more.

Advantageously, particularly high deflections or tilts of the actuator body can be achieved by means of the preferred MEMS actuator, in particular through the meander structure of the actuator arm comprising the two or more actuator sections. Furthermore, it is advantageous that possible degrees of freedom, for example with regard to tilting, can be adapted, for example by attaching one or more fixing elements and/or further actuator arms.

In another preferred embodiment, the MEMS actuator is characterized in that the actuator arm has a length between 10 μm and 10 mm, preferably between 50 μm and 1000 μm. Intermediate ranges from the aforementioned ranges may also be preferred, such as 10 μm to 100 μm, 100 μm to 200 μm, 200 μm to 300 μm, 300 μm to 400 μm, 400 μm to 500 μm, 500 μm to 1000 μm, 1 mm to 2 mm, 3 mm to 4 mm, 4 mm to 5 mm, 5 mm to 8 mm, or even 8 mm to 10 mm. A person skilled in the art will recognize that the aforementioned range limits can also be combined to obtain further preferred range, such as 10 μm to 500 μm, 500 μm to 1 mm or even 1 mm to 5 mm.

In another preferred embodiment, the MEMS actuator is characterized in that the actuator sections have a height between about 1 μm and about 1000 μm, preferably between about 10 μm and about 500 μm, and/or a thickness between about 100 nm and about 10 μm, preferably between about 500 nm and about 5 μm.

In a preferred embodiment, the height of the actuator sections is between 1 μm and 1000 μm, preferably between 10 μm and 500 μm. Intermediate ranges from the aforementioned ranges may also be preferred, such as 1 μm to 10 μm, 10 μm to 50 μm, 50 μm to 100 μm, 100 μm to 200 μm, 200 μm to 300 μm, 300 μm to 400 μm, 400 μm to 500 μm, 600 μm to 700 μm, 700 μm to 800 μm, 800 μm to 900 μm, or even 900 μm to 1000 μm. A person skilled in the art will recognize that the aforementioned range limits can also be combined to obtain other preferred ranges, such as 10 μm to 200 μm, 50 μm to 300 μm or even 100 μm to 600 μm.

In a preferred embodiment, the thickness of the actuator sections is between 100 nm and 10 μm, preferably between 500 nm and 5 μm. Intermediate ranges from the aforementioned ranges may also be preferred, such as 100 nm to 500 nm, 500 nm to 1 μm, 1 μm to 1.5 μm, 1.5 μm to 2 μm, 2 μm to 3 μm, 3 μm to 4 μm, 4 μm to 5 μm, 5 μm to 6 μm, 6 μm to 7 μm, 7 μm to 8 μm, 8 μm to 9 μm, or even 9 μm to 10 μm. A person skilled in the art will recognize that the aforementioned range limits can also be combined to obtain other preferred ranges, such as 500 nm to 3 μm, 1 μm to 5 μm or even 1500 nm to 6 μm.

The numerical values mentioned with regard to the length of the actuator arm or the shape of the actuator sections have proven to be advantageous in that they allow a particularly effective movement of the actuator body over a large angular range.

Preferably, the length of the actuator arm also corresponds to the number and design of the actuator sections. The more actuator sections there are and the longer the horizontal sections between the actuator sections, the longer the resulting actuator arm. The average person skilled in the art is able to select the appropriate sizes, depending on the application, to obtain the properties of the MEMS actuator in terms of deflectability and/or tiltability.

In another preferred embodiment, the MEMS actuator is characterized in that the at least one actuator arm comprises more than 3, 4, 5, 10, 15, 20, 30, 40, 50, 100 or more actuator sections.

As already explained, the number of actuator sections corresponds to the length of the actuator arm, the control signal to be applied and/or the deflection as such. The more actuator sections are provided, the longer the actuator arm becomes and the higher the deflection or tilt that can be achieved by the actuator, since more actuator sections in particular generate greater travel and/or torque in total. The number of actuator sections is easy for a person skilled in the art to configure or provide during a preferred method for producing the preferred MEMS actuator.

In another preferred embodiment, the MEMS actuator is characterized in that the actuator body is connected to the frame structure via one, two, three or four actuator arms, wherein the one, two, three or four actuator arms are preferably in a plane.

With the number of actuator arms, the deflection as such and/or the number of degrees of freedom of the actuator body can be optimized in a simple way and depending on the application purpose. Furthermore, a higher number of actuator arms advantageously enables a particularly safe connection to the actuator body, since a connection to the frame structure is given even if an actuator arm is not functional. Furthermore, a higher number of actuator arms allows the deflection and/or the actuation of the actuator body to be configured more effectively, as actuation is carried out from several sides via several actuator arms.

Furthermore, it is preferred that an electrode is present in contact with the respective first end of the actuator arms in order to enable the actuation by an electrical control signal. Thus, in preferred embodiments, two, three, four or more end-sided electrodes, i.e. in particular electrodes are present in contact with the respective first end of the two, three, four or more actuator arms. Preferably, the contacting with electronics, e.g. a current and/or voltage source, can be made with the electrodes at opposite ends between which the actuator arms are present, such that the actuator position(s) in the actuator sections can be controlled by means of the end-sided electrodes. Advantageously, it is not necessary to actuate the individual actuator sections of the respective actuator arms separately; instead, an advantageous actuation of the actuator body can be carried out by an end-side electronic contact, e.g. with the aid of an electrode, preferably in the form of an electrode pad.

By means of an actuator arm, tilting or rotation about a fixed pivot axis or a fixed pivot point can preferably be made possible.

On the other hand, if four actuator arms are attached, for example, which substantially have an angle of 90° to each other, this results in higher degrees of freedom with regard to the movability of the actuator body. For example, by actuating two opposing actuator arms, the actuator body can be moved or deflected out of the plane. By actuating one of the other two actuator arms, which are not responsible for the out-of-plane movement or deflection, a tilting of the actuator body can be superimposed. Likewise, when four actuator arms are attached, the actuator body can be tilted in directions that have a perpendicular component to the plane. Thus, a variety of movement forms and deflection options can be created for the actuator body.

In another preferred embodiment, the MEMS actuator is characterized in that the actuator body is present connected to the frame structure via two actuator arms, wherein the two actuator arms are present in a plane and comprise an angle of substantially 90° or an angle of substantially 180° in the plane.

A preferred arrangement of two actuator arms of substantially 180° to each other is characterized by a substantially horizontal extension of the actuator arms, preferably with the actuator body in the center. Preferably, the actuation is carried out with the aid of an electrical control signal in opposite phase, so that opposite lateral bendings of the actuator sections of the two actuator arms are generated and, for example, a movement and/or deflection of the actuator body out of the plane is made possible. Such vertical out-of-plane movement of the actuator body is illustrated, for example, in FIG. 4.

In the case of a preferred attachment of two actuator arms with a comprised angle between approx. 45° and approx. 135°, preferably of essentially 90°, there is an essentially orthogonal extension of the actuator arms to each other. A rotation or tilting about a first axis of rotation can preferably be effected by a first actuator arm and a rotation or tilting about a second axis of rotation can be effected by the second actuator arm. In this way, a MEMS actuator can be provided which enables a 2D tilting of the actuator body precisely and over a large angular range. A micromirror that can be provided in this way can be advantageously tilted or swiveled about two axes and can be used, for example, to direct a laser beam in a targeted and precise manner.

In a further preferred embodiment, the MEMS actuator is characterized in that the actuator body has a reflective surface at least in sections, particularly preferably in the form of a micromirror.

The preferred MEMS actuator has proven to be particularly advantageous in the context of micromirrors. Thus, large deflections, in particular in the form of large angles in relation to a tilt, can be advantageously achieved. Advantageously, particularly high tilting angles in a horizontal and/or in a vertical direction can be achieved in particular by the meander structure of the actuator arm comprising the two or more actuator sections. Here, the average person skilled in the art is aware that according to the principle of a (plane) mirror reflection, if the direction of the incident light remains unchanged and the (micro) mirror is rotated by a tilt angle of ω, the angle of reflection changes by 2ω (see e.g. Pang et al. (2022)). The average person skilled in the art is also able to adjust the deflections of the actuator body to specific tilt angles to suit particular application purposes. Advantageously, when designing the actuator body as a micromirror, large fields of view (FoV) can be realized. This makes the MEMS actuator suitable for a wide range of applications in which micromirrors are used, e.g. LiDAR applications and/or microscanners.

Furthermore, the frequency of movements and/or forms of movement of the actuator body can be controlled in a particularly simple manner, especially in relation to applications of micromirrors. For example, the frequency of the movement can be optimized by actuating the actuator arm via a control signal and/or by placing several actuator arms between the frame structure and the actuator body. This results in a variety of operating modes of the actuator body that have proven useful for micromirrors. Thus, the actuator body can advantageously undergo deflection at high frequencies. The operating principle of the actuator arm according to the invention also excels in this respect, since a plurality of actuator sections can be simultaneously excited by means of a control signal. The inertia of the MEMS actuator is thus reduced and undiminished precision can be achieved at high frequencies.

For example, the actuator body can undergo a deflection, in particular a tilting, about a rotation axis at a desired frequency. Likewise, the actuator body can advantageously be operated quasi-statically. Advantageously, both of the last-mentioned operating options of the preferred MEMS actuator are available.

Furthermore, the actuator body can be advantageously designed for a desired application as a micromirror by means of the preferred production process. Thus, the actuator body can be provided and dimensions and/or geometric shapes of the actuator body can be constructed in a particularly process-efficient manner, for example by means of known and simple etching processes of the substrate. For example, the actuator body can have an extension of about 0.1 mm to 5 mm, preferably 0.5 mm to 2 mm. Consequently, the design of the actuator body in particular can ensure a high output of light from micromirrors. The actuator body may have in cross-section, for example, a shape selected from a group comprising a square, an ellipse, a circle, a rectangle, a triangle, a pentagon, a hexagon, an octagon or any other regular or irregular geometric figure.

In particular, it is preferred that the actuator body has a reflective surface at least in sections. It is particularly preferred that the actuator body itself is designed as a micromirror. Preferably, the actuator body can already be called a micromirror if it already has a reflective surface at least in sections. Particularly preferably, the actuator body has a reflective surface along a front side.

There are preferably several possibilities for the provision of at least partially reflective surfaces of the actuator body. For example, the actuator body can be formed from a substrate which already has an at least partially reflective surface, such that advantageously no further production steps are required and thus an advantageous process efficiency results. It may also be preferable to apply an at least partially reflective surface by one or more coating processes of a correspondingly reflective material.

The reflection as such is preferably regulated by the choice of materials to create the at least partially reflective surface of the actuator body. The choice of materials is preferably also related to which wavelength range of light is to be reflected. Preferably, for the provision of a reflective surface at least in sections, a material may be selected from a group comprising aluminum, silver and/or gold. With regard to the materials, one can also speak of so-called protected aluminum, enhanced aluminum, protected silver, bare and/or protected gold.

The term “Protected” preferably refers to an additional coating by a dielectric. The term “Enhanced” preferably refers to a multilayer dielectric coating. The term “bare” preferably refers to an unprotected material. Advantageously, a dielectric coating layer on a metal allows better handling of the component, increases the durability of the metal coating and provides protection against oxidation. The dielectric layer(s) may also preferably be such that it increases the reflection coefficient of the metal coating in certain spectral ranges. Thus, a high light yield can be ensured in a particularly simple manner by the design of the actuator body through a corresponding increase in the reflection coefficient.

If the actuator body is designed as a micromirror, the MEMS actuator in combination with the micromirror may be referred to as a micromirror actuator in the context of the invention.

The micromirror actuator can be considered as a spatial light modulator. Preferably, the micromirror actuator can function as a microscanner. Advantageously, the preferred microscanner has a large optical scanning range that can preferably be operated at high (oscillation) frequencies. Advantageously, one-dimensional, two-dimensional or three-dimensional objects can be optimally scanned. The micromirror actuator can be used as a microscanner for projection displays, image acquisition, e.g. for technical and medical endoscopes, in spectroscopy, in laser marking and processing of materials, in object measurement/triangulation, in 3D cameras, in object recognition, in 1-D and 2D light curtains, in confocal microscopy and/or in fluorescence microscopy. In microscanners, the modulation of a beam is preferably performed on a continuously moving micromirror.

It may also be preferable to arrange several micromirror actuators as an array, whereby the individual micromirrors can preferably be discretely deflected over time. This achieves the deflection of partial beams or a phase-shifting effect of light beams. By means of a corresponding array arrangement, for example in the form of a matrix, an image projection can take place on a suitable projection screen.

In another preferred embodiment, the MEMS actuator is characterized in that the frame structure has been formed from a substrate, the substrate comprising a material preferably selected from a group comprising monocrystalline silicon, polysilicon, silicon dioxide, silicon carbide, silicon germanium, silicon nitride, nitride, germanium, carbon, gallium arsenide, gallium nitride, indium phosphide and/or glass.

The materials mentioned are easy and inexpensive to process in semiconductor and/or microsystem technology and are suitable for large-scale production. The frame structure and/or further components of the preferred MEMS actuator, for example the actuator sections, the actuator body, etc., can be flexibly produced due to the materials and/or production methods. In particular, it is preferably possible to produce the preferred MEMS actuator comprising an actuator arm together with a frame structure in a (semiconductor) process, preferably on and/or from a substrate. This further simplifies and cheapens the production, such that a compact and robust MEMS actuator can be provided at low cost.

In a further aspect, the invention preferably relates to a method of producing a preferred MEMS actuator comprising the following steps:
Etching of a substrate, preferably starting from a front side, to form a structure, preferably a meander structure,
An application of at least one layer comprising an actuator material to provide an actuator arm comprising two or more actuator sections,
Etching of the substrate, preferably starting from a rear side, to expose the actuator arm, such that the actuator arm comprising the two or more actuator sections is connected at a first end to a frame structure formed by the substrate and at a second end to an actuator body, wherein the actuator sections are oriented substantially perpendicular to a longitudinal axis of the actuator arm so that a movement of the actuator body can be effected by actuating the actuator sections to effect lateral bendings.

The average person skilled in the art will recognize that technical features, definitions and advantages of preferred embodiments of the described MEMS actuator also apply to the described production process and vice versa.

The preferred production process has proven to be a particularly process-efficient method to provide the preferred MEMS actuator, as common process steps of semiconductor and/or microsystem technology can be used. In particular, in the context of producing a MEMS actuator for moving a micromirror, the preferred method has proven to be particularly useful.

Preferably, a substrate is first provided. After providing the substrate, it is preferred to etch the substrate, preferably starting from a front side, to form a structure, preferably a meander structure. Etching the substrate preferably means removing the substrate material to form the structure, preferably the meander structure. The removal of the substrate material may be in the form of depressions, for example leaving cavities on the substrate.

The etching of the substrate is preferably performed by the use of an etching method (also known as an etching process). In preferred embodiments, the etching of the substrate is performed by wet chemical etching processes and/or dry etching processes, preferably physical and/or chemical dry etching processes, particularly preferably by reactive ion etching and/or reactive ion deep etching (Bosch process), or by a combination of the aforementioned etching processes.

The aforementioned etching processes are known to the person skilled in the art. Depending on the desired design of the structure of the substrate, in particular the meander structure, advantageous processes can be selected to ensure efficient implementation.

After providing a structure in the substrate, preferably a meander structure, application of at least one layer comprising an actuator material to provide the actuator arm comprising two or more actuator sections is preferred.

Preferably, the application of the at least one layer comprising the actuator material is performed by using a coating method within a coating apparatus. For example, the coating method may be selected from a group comprising spray coating, mist coating and/or steam coating.

Preferably, the coating is carried out within a coating apparatus, which may be a physical coating apparatus or chemical coating apparatus, preferably plasma assisted chemical coating apparatus, low pressure chemical and/or epitaxial coating apparatus.

Furthermore, it is preferred that etching of the substrate is performed, preferably starting from a rear side, to expose the actuator arm. Preferably, one or more of the enumerated etching methods can be used to expose the actuator arm.

Thus, according to the preferred method, the actuator arm comprising the two or more actuator sections is present, which is connected at a first end to a frame structure formed by the substrate and at a second end to an actuator body. The actuator sections are preferably aligned substantially perpendicular to a longitudinal axis of the actuator arm, such that a movement of the actuator body can be effected by actuating the actuator sections.

Preferably, the actuator body is formed from a piece of the substrate, wherein preferably the formation of the actuator body is performed by a corresponding etching of the substrate. Furthermore, it may be preferred to functionalize the actuator body, preferably by applying or coating a reflective material at least in sections, so that the actuator body is present as a micromirror.

In a further preferred embodiment, the method is characterized in that a meander structure is formed by etching the substrate, preferably starting from a front side, wherein regions of the meander structure of the substrate, which serve to form the two or more actuator sections, are oriented orthogonally to the surface of the substrate.

The portions of the substrate that are not removed by the etching are preferably used to provide the meander structure. It is further preferred to apply at least one layer comprising an actuator material to the meander structure. Preferably, two layers are applied, wherein the two layers may be one layer comprising an actuator material and a mechanical support layer or two layers comprising an actuator material. Preferably, by applying two layers, the mechanical bimorph is formed, wherein an actuator section is to be understood as a mechanical bimorph and this is arranged vertically to the substrate surface by the etching. By means of a preferred etching, preferably starting from a rear side, the actuator arm is exposed.

The regions of a meander structure at which the actuator sections (vertical sections) of the actuator arm are formed thus preferably extend substantially vertically to the substrate surface from which the frame structure and/or the actuator arm was formed. In the finished MEMS actuator, the actuator arm preferably extends substantially horizontally to the (original) substrate surface (e.g. a wafer), while the actuator sections are arranged vertically to the (original) substrate surface.

The invention will be explained below with reference to further figures and examples. The examples and figures serve to illustrate preferred embodiments of the invention without being limited to them.

### BRIEF DESCRIPTION OF THE DRAWINGS

FIG. 1 Schematic representation of a preferred embodiment of a MEMS actuator

FIGS. 2 (A) and (B): Schematic representations of a preferred embodiment of a MEMS actuator with an actuator arm for deflection or tilting of the actuator body

FIGS. 3 (A) and (B): Schematic representation of a further preferred embodiment of a MEMS actuator with an actuator arm for tilting the actuator body about a stationary axis of rotation (fixing means)

FIG. 4 Schematic representation of a further preferred embodiment of a MEMS actuator with two opposing actuator arms for vertical translation of the actuator body.

FIGS. 5 (A) and (B): Simulations of preferred embodiments of a MEMS actuator.

### DETAILED DESCRIPTION

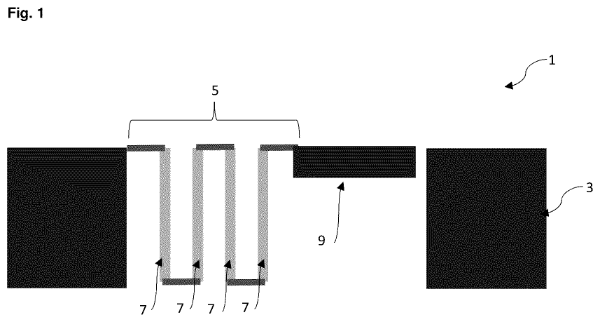

FIG. 1 is a schematic representation of a preferred embodiment of a MEMS actuator 1.

The MEMS actuator 1 comprises a frame structure 3 and an actuator arm 5. The actuator arm 5 is connected at a first end to the frame structure 3 and at a second end to an actuator body 9. Further, the actuator arm 5 comprises a meander structure comprising actuator sections 7, wherein the actuator sections 7 are oriented substantially perpendicular to a longitudinal axis of the actuator arm 5. Furthermore, the actuator arm 5 comprises at least one layer of an actuator material (not shown), such that a movement of the actuator body 9 can be effected by actuating the actuator sections 7.

The MEMS actuator 1 advantageously achieves particularly high deflections, in particular in the form of high tilting angles of the actuator body 9. The advantageous achievement of high tilting angles of the actuator body 9 is made possible in particular by the design of the actuator arm 5, in particular by the meander structure comprising actuator sections 7 which are oriented substantially perpendicular to the longitudinal axis of the actuator arm 5.

The meander structure results in a greater distance and thus a higher moment (product of force and displacement) and consequently also a higher deflectability of the actuator body 9, in particular in the form of a higher tilt angle.

The beneficial effect of achieving higher deflections of the actuator body 9, in particular higher tilt angles, is useful for a variety of applications. For example, the MEMS actuator 1 is particularly well suited for the movement and/or tilting of micromirrors. Advantageously, the MEMS actuator 1 can be operated with a variety of modes of action. Further, advantageously, a potential user of the preferred MEMS actuator 1 can select an operating principle from a plurality of physical principles, for example, actuation by an electrical or thermal signal, to effect movement of the actuator body 9. The use of an actuator arm 5 with a meander structure to move the actuator body 9 is thus not limited to certain actuator principles.

Furthermore, the MEMS actuator 1 is characterized by a process-efficient producibility. The MEMS actuator 1 can be provided with common methods of microsystem and/or semiconductor technology, in particular the structuring of the meander structure as well as the design of the actuator arm 5. It is particularly advantageous that the MEMS actuator 1 can be produced from a substrate and thus within a single process sequence. For example, components such as the frame structure 3, the actuator arm 5 comprising actuator sections 7 and/or the actuator body 9 can be formed from a substrate.

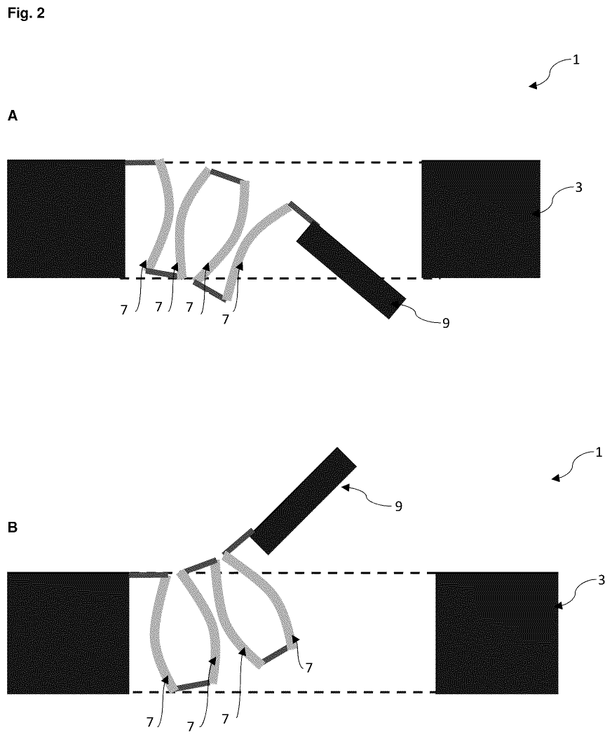

FIGS. 2 (A) and (B) is a schematic representation of a preferred MEMS actuator 1 with an actuator arm 5 and its use for a deflection or tilting of the actuator body 9. FIGS. 2 (A) and (B) shows two phases of a tilting of the actuator body 9. In FIG. 2 (A) the actuator body is tilted in the direction of a front side (“upwards”), while in FIG. 2 (B) the actuator body 9 is tilted in the direction of a rear side (“downwards”). Here, high deflections of the actuator body 9, in particular high tilting angles, are obtained by actuating the actuator sections 7. The actuator body 9 can be tilted by at least 10°, preferably by at least 20°, particularly preferably by at least 40°, especially preferably by at least 60°. Since the actuator body 9 is not fixed, the tilting or rotation of the actuator body 9 is accompanied by a vertical translation out of the plane.

If such a translational movement is not desired, it may be preferable to restrict the (translational) degree of freedom of the actuator body 9 by means of a fixing element.

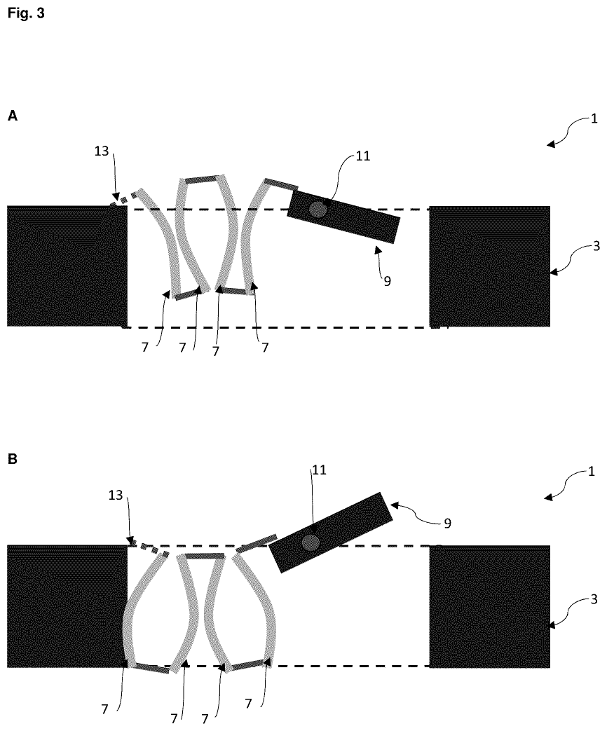

FIGS. 3 (A) and (B) shows a schematic representation of a preferred embodiment of a MEMS actuator 1, which has a fixing element 11 connected to the actuator body 9. The fixing element 11 prevents a translation of the actuator body 9 in a vertical direction, so that the actuator body 9 can be tilted along a substantially stationary pivot point and/or a pivot axis by applying the control signal. Analogous to FIGS. 2 (A) and (B), in FIG. 3A the actuator body 9 is tilted in the direction of a front side, while in FIG. 3 (B) the actuator body 9 is tilted in the direction of a rear side. In contrast to the embodiment of FIGS. 2 (A) and (B), however, there is no superimposed vertical translational movement. The adjustment of the tilting is obtained by fixing element 11.

Furthermore, a mechanically flexible connector 13 is present at the first end of the actuator arm 5, which is connected to the frame structure 3. Due to the mechanically flexible connector 13, there is advantageously a reduced mechanical resistance at the first end and thus at the connection point of the actuator arm 5 with the frame structure 3, so that the movement of the actuator body 9 takes place with particularly low mechanical resistance. In addition to flexibility, a mechanically flexible connector 13 is preferably characterized by elastic properties in order to ensure a restoring force to a preferred position. Preferably, a mechanically flexible connector 13 can be a MEMS spring.

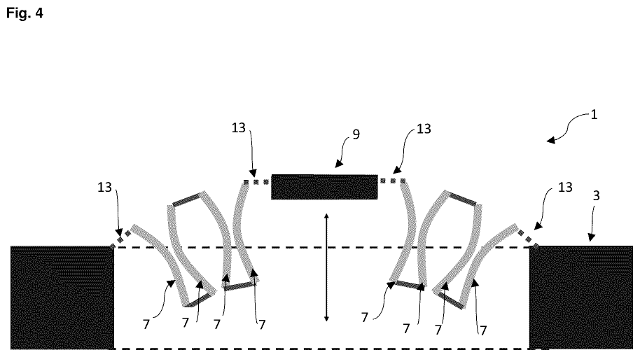

FIG. 4 illustrates another preferred embodiment of a MEMS actuator 1.

Here, the MEMS actuator 1 comprises an actuator body 9 which is connected to the frame structure 3 via two actuator arms 5. The two actuator arms 5 are present in a plane and comprise an angle of substantially 180°. The attachment of two actuator arms 5, in particular along a plane within an angular range of 180°, allows in particular in an efficient way a deflection of the actuator body 9 out of the plane. The attachment of two actuator arms 5 of substantially 180° to each other is characterized by an essentially horizontal extension of the actuator arms 5, with the actuator body 9 being present in the center.

Furthermore, a mechanically flexible connector 13 is present at both the first end and the second end of the actuator arms 5, so that the deflection and/or movement of the actuator body 9 is facilitated during actuation.

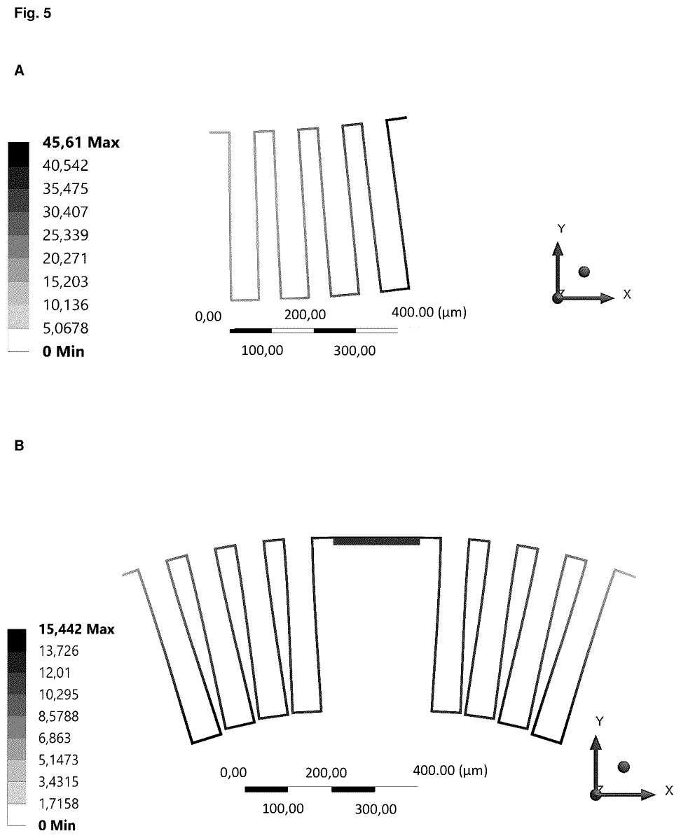

In FIGS. 5 (A) and (B) simulations of the MEMS actuator 1 are shown, in particular during a deflection of the actuator arm 5. The simulation results shown are based on a finite element method.

In FIG. 5 (A) the actuator arm 5 from FIG. 2 is simulated without the presence of the actuator body 9. Here an actuator arm 5 with a meander structure and 8 actuator sections is shown, which is fixed at a first end (on the left in FIG. 5 (A)) to a frame structure (not shown). The second end of the actuator arm—to which an actuator body can be attached—is not fixed. In the simulated movement, the second end is deflected or translated in positive y-direction (vertical direction) and negative x-direction (horizontal) while tilting occurs. The fixing at the first end is shown on the left at the blue end (displacement=0). The tilt angle here is approx. 8°.

From the simulation, it can be seen that during actuation, the individual actuator sections are displaceable, especially at vertical end-side sections of the actuator sections. Consequently, the mechanical resistance of the actuator arm, in particular of the actuator sections, is lower than if the actuator arm were provided by a flat or straight structure, so that high deflections can be achieved.

In FIG. 5 (B) a MEMS actuator 1 is simulated according to the preferred form of FIG. 4. The modelled actuator arm 5 is fixed with its first end (displacement=0). An actuator body 9 can be attached to its second end, which is also held on an opposite side by a second actuator arm 5 as illustrated in FIG. 4. The vertical displacement of the actuator body 9 is approx. 10 μm in the y-direction in the simulation.

### BIBLIOGRAPHY

Algamili, Abdullah Saleh, et al. “A review of actuation and sensing mechanisms in mems-based sensor devices.” Nanoscale research letters 16.1 (2021): 1-21.
Wang, Dingkang, Connor Watkins, and Huikai Xie. “MEMS mirrors for LiDAR: a review.” Micromachines 11.5 (2020): 456.
Katal, Goldy, Nelofar Tyagi, and Ashish Joshi. “Digital light processing and its future applications.” International journal of scientific and research publications 3.1 (2013): 2250-3153.
Lee, Benjamin. “Introduction to ±12 degree orthogonal digital micromirror devices (dmds).” Texas Instruments (2008): 2018-02.
Holmström, Sven TS, Utku Baran, and Hakan Urey. “MEMS laser scanners: a review.” Journal of Microelectromechanical Systems 23.2 (2014): 259-275.
Pang, Yajun, et al. “Design Study of a Large-Angle Optical Scanning System for MEMS LIDAR.” Applied Sciences 12.3 (2022): 1283.

### REFERENCE LIST

1 MEMS actuator
3 Frame structure
Actuator arm
7 Actuator section
9 Actuator body
11 Fixing element
13 Connector

What is claimed is:

1. A MEMS actuator comprising a frame structure and at least one actuator arm, wherein the actuator arm is connected at a first end to the frame structure and at a second end to an actuator body, wherein the at least one actuator arm has a meander structure comprising two or more actuator sections, wherein the two or more actuator sections are oriented substantially perpendicular to a longitudinal axis of the actuator arm and comprise at least one layer of an actuator material and wherein a movement of the actuator body can be effected by actuation of the two or more actuator sections.

2. The MEMS actuator according to claim 1, wherein the movement of the actuator body comprises translation, rotation, torsion and/or tilting.

3. The MEMS actuator according to claim 1, wherein the two or more actuator sections are formed by applying at least one layer comprising an actuator material to a meander structure of a substrate.

4. The MEMS actuator according to claim 3, wherein regions of the meander structure of the substrate are oriented orthogonally to the surface of the substrate to form the two or more actuator sections.

5. The MEMS actuator according to claim 1, wherein the two or more actuator sections comprise at least two layers.

6. The MEMS actuator according to claim 5, wherein one layer comprises an actuator material and a second layer comprises a mechanical support material and/or wherein both layers comprise an actuator material.

7. The MEMS actuator according to claim 1, wherein the actuator material comprises a piezoelectric material, a polymer piezoelectric material, electroactive polymers (EAP) and/or a thermosensitive material.

8. The MEMS actuator according to claim 1, wherein the actuator arm is in contact with at least one electrode and the actuator sections are actuated by an electrical control signal to effect lateral bendings or deflections.

9. The MEMS actuator according to claim 1, wherein the MEMS actuator has a fixing element which is connected to the actuator body so that the actuator body can be tilted along a pivot point and/or a pivot axis by applying the control signal.

10. The MEMS actuator according to claim 1, wherein the first end of the actuator arm is connected to the frame structure via a mechanically rigid or flexible connector.

11. The MEMS actuator according to claim 1, wherein by actuating the two or more actuator sections, the actuator body can be tilted by at least 10° about a pivot point.

12. The MEMS actuator according to claim 1, wherein the at least one actuator arm comprises more than 3 actuator sections.

13. The MEMS actuator according to claim 1, wherein the actuator body is connected to the frame structure via one, two, three or four actuator arms.

14. The MEMS actuator according to claim 13, wherein the one, two, three or four actuator arms are in one plane.

15. The MEMS actuator according to claim 1, wherein the actuator body is connected to the frame structure via two actuator arms, the two actuator arms being in a plane and enclosing an angle of substantially 90° or an angle of substantially 180° in the plane.

16. The MEMS actuator according to claim 1, wherein the actuator body has a reflective surface at least in sections.

17. The MEMS actuator according to claim 16, wherein the reflective surface is in the form of a micromirror.

18. A method of producing the MEMS actuator according to claim 1 comprising the steps of:
etching of a substrate to form a structure,
applying at least one layer comprising an actuator material to provide an actuator arm comprising two or more actuator sections, and
etching of the substrate to expose the actuator arm,
so that the actuator arm comprising the two or more actuator sections is connected at a first end to a frame structure formed by the substrate and at a second end to an actuator body, the actuator sections being aligned substantially perpendicular to a longitudinal axis of the actuator arm, so that a movement of the actuator body can be effected by actuating the actuator sections to effect lateral bendings.

19. The method of claim 18, wherein the first etching of the substrate forms a meander structure.

20. The method of claim 18, wherein the first etching of the substrate is started from a front side and wherein the second etching of the substrate is started from a rear side.

21. The method according to claim 18, wherein a meander structure is formed by etching the substrate, wherein regions of the meander structure of the substrate, which serve to form the two or more actuator sections, are oriented orthogonally to the surface of the substrate.

22. The method of claim 21, wherein the meander structure is formed by etching the substrate from a front side.
